(19) United States
(12) Patent Application Publication
(10) Pub. No.: US 2026/0013132 A1
(43) Pub. Date: Jan. 8, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Na Yeong YANG, Icheon-si Gyeonggi-do (KR)

(73) Assignee: SK hynix Inc., Icheon-si Gyeonggi-do (KR)

(21) Appl. No.: 19/024,556

(22) Filed: Jan. 16, 2025

(30) Foreign Application Priority Data
Jul. 4, 2024 (KR) 10-2024-0088275

(51) Int. Cl. H10B 43/27; H10B 43/10

(52) U.S. Cl. CPC H10B 43/27; H10B 43/10

(57) ABSTRACT

A memory device includes conductive layers and interlayer insulting layers alternately stacked in a first direction as well as a contact plug extending in the first direction from a first conductive layer among the conductive layers. The memory device also includes a spacer surrounding a side surface of the contact plug, wherein the spacer includes first material patterns and second material patterns alternately stacked in the first direction.

### CROSS-REFERENCE TO RELATED APPLICATION

The present application claims priority under 35 U.S.C. § 119 (a) to Korean patent application number 10-2024-0088275 filed on Jul. 4, 2024, in the Korean Intellectual Property Office, the entire disclosure of which application is incorporated herein by reference.

### BACKGROUND

### 1. Technical Field

Various embodiments of the present disclosure generally relate to a memory device and a manufacturing method of the memory device, and more particularly, to a memory device including a three-dimensional memory block and a method of manufacturing the memory device.

### 2. Related Art

A non-volatile memory device may retain stored data even when supplied power is interrupted. A non-volatile memory device may have a two-dimensional structure or a three-dimensional structure according to how memory cells are arranged. Memory cells of a non-volatile memory device having a two-dimensional structure may be arranged in a single layer on a substrate, and memory cells of a non-volatile memory device having a three-dimensional structure may be stacked in a vertical direction on the substrate. Because a degree of integration of the non-volatile memory device having the three-dimensional structure is higher than that of the non-volatile memory device having the two-dimensional structure, electronic devices are increasingly being manufactured with non-volatile memory devices having a three-dimensional structure.

### SUMMARY

According to an embodiment of the present disclosure, a memory device may include conductive layers and interlayer insulting layers alternately stacked in a first direction, a contact plug extending in the first direction from a first conductive layer among the conductive layers, and a spacer surrounding a side surface of the contact plug. The spacer may include first material patterns and second material patterns alternately stacked in the first direction.

According to an embodiment of the present disclosure, a method of manufacturing a memory device may include: alternately stacking sacrificial layers and interlayer insulating layers in a first direction; forming an opening into the stacked layers exposing a first interlayer insulating layer among the interlayer insulating layers; forming a spacer on side surfaces of the sacrificial layers and the interlayer insulating layers exposed through the opening, wherein the spacer includes first material patterns and second material patterns alternately stacked in the first direction; removing a portion of the first interlayer insulating layer exposed through the opening to expose a first sacrificial layer among the sacrificial layers; forming a sacrificial pillar contacting the first sacrificial layer in the opening; and replacing the sacrificial layers and the sacrificial pillar with a conductive material.

### BRIEF DESCRIPTION OF THE DRAWINGS

FIG. 1 is a diagram illustrating a memory device according to an embodiment of the present disclosure;

FIG. 2 is a diagram illustrating a memory device according to an embodiment of the present disclosure;

FIGS. 3A and 3B are diagrams illustrating a contact plug and a spacer according to an embodiment of the present disclosure;

FIGS. 4A to 4F are diagrams illustrating a manufacturing method of forming a contact plug and a spacer according to an embodiment of the present disclosure;

FIG. 5 is a diagram illustrating a structure of a contact plug according to another embodiment of the present disclosure;

FIG. 6 is a diagram illustrating a memory card system to which a memory device according to an embodiment of the present disclosure is applied; and

FIG. 7 is a diagram illustrating a solid-state drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, some embodiments of the present disclosure are described in detail with reference to the accompanying drawings for those skilled in the art to be able to readily implement the technical spirit of the present disclosure.

Some embodiments are directed to a memory device capable of improving the performance of contact plugs and simplifying the forming process of the contact plugs and a method of manufacturing the memory device.

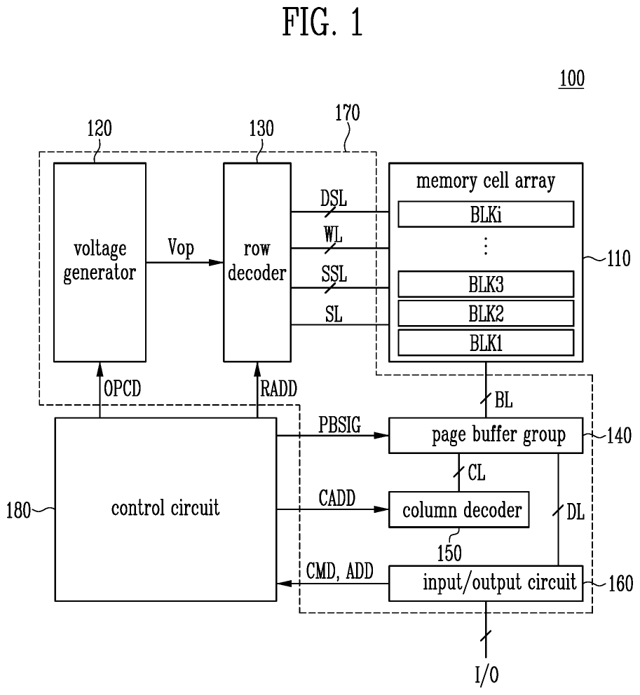

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

The first to ith memory blocks BLK1 to BLKi may have a three-dimensional structure. Each of the first to ith memory blocks BLK1 to BLKi may include a cell region and a contact region. Memory blocks having a three-dimensional structure may include memory cells stacked in a vertical direction on a substrate in a cell region. The memory blocks having the three-dimensional structure may include contact plugs that are extended in the vertical direction from the drain select lines DSL, the word lines WL, and the source select lines SSL in a contact region.

Each of the memory cells may store one, two, or more bits of data according to a program method. For example, a method in which one bit of data is stored in one memory cell is referred to as a single-level cell (SLC) method, and a method in which two bits of data are stored in one memory cell is referred to as a multi-level cell (MLC) method. A method in which three bits of data are stored in one memory cell is referred to as a triple-level cell (TLC) method, and a method in which four bits of data are stored in one memory cell is referred to as a quad-level cell (QLC) method. In addition, five or more bits of data may be stored in one memory cell.

The peripheral circuit 170 may be configured to perform a program operation that stores data in the memory cell array 110, a read operation that outputs data stored in the memory cell array 110, and an erase operation that erases data stored in the memory cell array 110. The peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to receiving the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off drain select transistors or source select transistors. For example, the turn-off voltages may be set to 0 V. The pre-charge voltages may be higher than 0 V and may be applied to bit lines during a read operation. The verify voltages may be used during a verify operation to determine whether threshold voltages of selected memory cells have been increased to a target level. The verify voltages may be set to various levels according to the target level, and may be applied to a selected word line.

The read voltages may be applied to a selected word line during a read operation of selected memory cells. For example, the read voltages may be set to various levels according to a program method of the selected memory cells. The pass voltages may be applied to unselected word lines among the word lines WL during a program operation or a read operation, and may be used to turn on memory cells coupled to the unselected word lines. The erase voltages may be used during an erase operation to erase memory cells included in a selected memory block, and may be applied to the source line SL.

The row decoder 130 may be configured to transfer the operating voltages Vop to the drain select lines DSL, the word lines WL, the source select lines SSL, and the source line SL that are coupled to the selected memory block according to a row address RADD. For example, the row decoder 130 may be coupled to the voltage generator 120 through global lines, and may be coupled to the first to ith memory blocks BLK1 to BLKi through the drain select lines DSL, the word lines WL, the source select lines SSL, and the source line SL.

The page buffer group 140 may include page buffers (not shown) respectively coupled to the first to ith memory blocks BLK1 to BLKi. The page buffers may be coupled to the first to ith memory blocks BLK1 to BLKi through the bit lines BL, respectively. During a read operation, the page buffers may sense a current or a voltage of bit lines, which varies according to threshold voltages of selected memory cells, and may temporarily store sensed data in response to page buffer control signals PBSIG.

The column decoder 150 may be configured to transfer data between the page buffer group 140 and the input/output circuit 160 in response to a column address CADD. For example, the column decoder 150 may be coupled to the page buffer group 140 through column lines CL and may transfer enable signals through the column lines CL. The page buffers included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer the command CMD and the address ADD, which are received from an external controller, to the control circuit 180 through the input/output lines I/O, and may transfer data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 may control the peripheral circuit 170 to perform the program operation of a memory block selected by the address ADD. When the command CMD input to the control circuit 180 corresponds to a read operation, the control circuit 180 may control the peripheral circuit 170 to perform the read operation of the memory block selected by the address ADD and output read data. When the command CMD input to the control circuit 180 corresponds to an erase operation, the control circuit 180 may control the peripheral circuit 170 to perform the erase operation of the selected memory block.

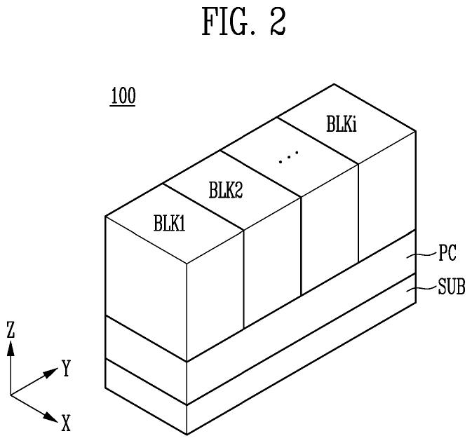

FIG. 2 is a diagram illustrating the memory device 100 according to an embodiment of the present disclosure.

Referring to FIG. 2, the memory device 100 may include a peripheral circuit structure PC and the first to ith memory blocks BLK1 to BLKi disposed over a substrate SUB. The first to ith memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include the row decoder 130, the column decoder 150, the page buffer group 140, and the control circuit 180 which constitute a circuit for controlling the operations of the first to ith memory blocks BLK1 to BLKi. For example, the peripheral circuit structure PC may include one or more of an NMOS transistor, a PMOS transistor, a resistor, and a capacitor that are electrically coupled to the first to ith memory blocks BLK1 to BLKi. The peripheral circuit structure PC may be disposed between the substrate SUB and the first to ith memory blocks BLK1 to BLKi.

Each of the first to ith memory blocks BLK1 to BLKi may include a source structure, bit lines, cell strings that are electrically coupled between the source structure and the bit lines, word lines that are electrically coupled to the cell strings, and select lines that are electrically coupled to the cell strings. Each of the cell strings may include memory cells and select transistors that are coupled in series by a cell plug. Each of the select lines may serve as a gate electrode of a corresponding select transistor, and each of the word lines may serve as a gate electrode of a corresponding memory cell. Each of the first to ith memory blocks BLK1 to BLKi may include the word lines and contact plugs that are coupled to the select lines. Voltages may be applied to the word lines and the select lines, respectively, through the contact plugs.

In another embodiment, the substrate SUB, the peripheral circuit structure PC, and the first to ith memory blocks BLK1 to BLKi may be stacked in reverse order with respect to the order shown in FIG. 2. For example, the peripheral circuit structure PC may be disposed over the first to ith memory blocks BLK1 to BLKi.

In another embodiment, contrary to FIG. 2, the peripheral circuit structure PC may be disposed in an area of the substrate SUB that does not overlap the first to ith memory blocks BLK1 to BLKi. For example, the peripheral circuit structure PC and the first to ith memory blocks BLK1 to BLKi may be respectively disposed in areas of the substrate SUB that do not overlap each other.

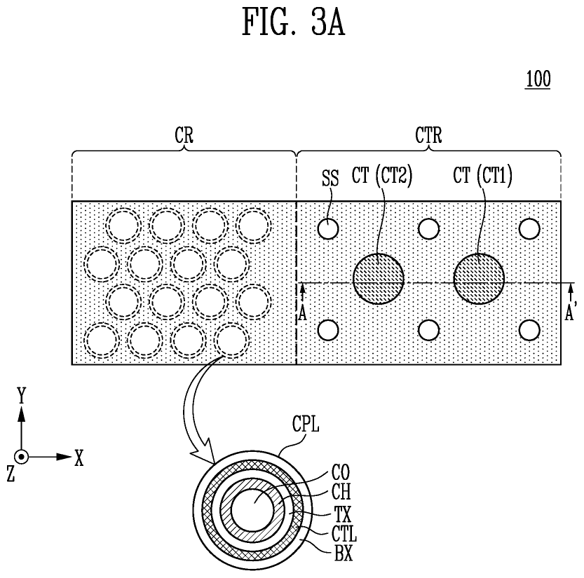

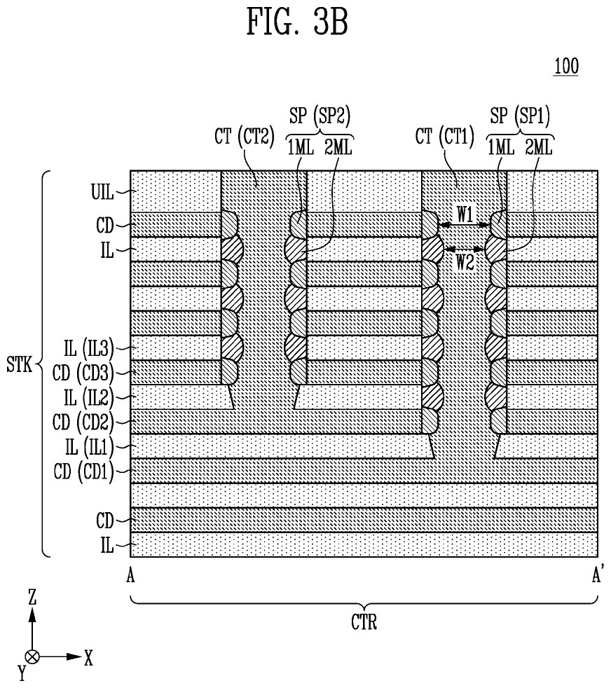

FIGS. 3A and 3B are diagrams illustrating a contact plug and a spacer according to an embodiment of the present disclosure. FIG. 3A is a plan view illustrating a layout of a cell region CR and a contact region CTR of the memory device 100. FIG. 3B shows a cross-section taken along line A-A′ of FIG. 3A.

Referring to FIG. 3A, the memory device 100 may include the cell region CR and the contact region CTR. For example, the contact region CTR may extend in an X direction from the cell region CR. In some other embodiments, unlike those shown in FIG. 3A, the contact region CTR may extend in a Y direction or both in the X and Y directions from the cell region CR. In addition, the cell region CR and the contact region CTR may be disposed in various manners.

Cell plugs CPL may be located in the cell region CR. The cell plugs CPL may extend in a Z direction in the cell region CR. Contact plugs CT may be located in the contact region CTR. The contact plugs CT may extend in the Z direction in the contact region CTR.

The cell plugs CPL may be arranged in the X-Y plane in the cell region CR. Each of the cell plugs CPL may extend in the Z direction. Each of the cell plugs CPL may include a blocking layer BX, a charge trap layer CTL formed along an inner wall of the blocking layer BX, a tunnel isolation layer TX formed along an inner wall of the charge trap layer CTL, a channel layer CH formed along an inner wall of the tunnel isolation layer TX, a core pillar CO in the channel layer CH, or a combination of at least two of these elements. The blocking layer BX and the tunnel isolation layer TX may include an oxide layer. For example, the blocking layer BX and the tunnel isolation layer TX may include a silicon oxide layer, a silicon nitride layer, or a combination thereof. The charge trap layer CTL may include a nitride layer or a variable resistance material. The channel layer CH may include a conductive layer, for example, a doped silicon layer. The channel layer CH may be replaced with an electrode structure. The core pillar CO may include an insulating layer or a conductive layer. Each of the blocking layer BX, the charge trap layer CTL, the tunnel isolation layer TX, the channel layer CH, and the core pillar CO included in the cell plug CPL may extend in the Z direction. A capping layer may further be formed over the core pillar CO to enhance the electrical characteristics of the select transistors included in each cell string.

The contact plugs CT may be arranged in the X direction in the contact region CTR. In some other embodiments, unlike those shown in FIG. 3A, the contact plugs CT may be arranged in the Y direction in the contact region CTR. Alternatively, a portion of the contact plugs CT may be arranged in the X direction and another portion of the contact plugs CT may be arranged in the Y direction. For example, the contact plugs CT may have different arrangements in the X-Y plane. In addition, the contact plugs CT may be arranged differently in the contact region CTR.

Each of the contact plugs CT may have a circular or elliptical shape in a cross-sectional plan view. In some other embodiments, unlike those shown in FIG. 3A, the contact plugs CT may have various shapes, for example, each of the contact plugs CT may have a polygonal shape, a linear shape, or the like in a cross-sectional plan view.

The contact plugs CT may include a first contact plug CT1 and a second contact plug CT2. The first contact plug CT1 and the second contact plug CT2 may be spaced apart from each other in the X direction. A length (e.g., a height or a depth) of the first contact plug CT1 and a length of the second contact plug CT2 in the Z direction may differ from each other. Structures of the first contact plug CT1 and the second contact plug CT2 are described below with reference to FIG. 3B.

The number of cell plugs CPL and contact plugs CT is not limited to that shown in FIG. 3A. For example, the number of contact plugs CT may vary according to the number of stacked layers included in a memory block (e.g., the first memory block BLK1). In addition, the locations of the cell plugs CPL and the contact plugs CT are not limited to those shown in FIG. 3A, and the cell plugs CPL and the contact plugs CT may be formed in various locations. For various embodiments, the cell plugs CPL and the contact plugs CT include the features described below with reference to FIG. 3B.

Support structures SS may be located in the contact region CTR. The support structures SS may extend in the Z direction in the contact region CTR. The support structures SS may be formed separately from the contact plugs CT. The support structures SS may support layers included in a memory block during a forming process of the memory block. The support structures SS may include an insulating material such as an oxide or a nitride. The size, shape, location, quantity, and arrangement of the support structures SS are not limited to those shown in FIG. 3A.

Referring to FIG. 3B, the memory device 100 may include a stack structure STK in which conductive layers CD and interlayer insulating layers IL are alternately stacked. The conductive layers CD and the interlayer insulating layers IL may be stacked in the Z direction. The stack structure STK may extend in the X and Y directions. The stack structure STK may further include an upper insulating layer UIL. The upper insulating layer UIL may be disposed over an uppermost conductive layer CD among the conductive layers CD. The upper insulating layer UIL may have a greater thickness than each of the interlayer insulating layers IL. The conductive layers CD may include tungsten (W), cobalt (Co), nickel (Ni), molybdenum (Mo), silicon (Si), polysilicon (poly-Si), or a combination of at least two of these materials. For example, the conductive layers CD may have a single layer or multiple layers. The interlayer insulating layers IL and the upper insulating layer UIL may include an oxide layer (e.g., a silicon oxide layer).

FIG. 3B shows the contact region CTR of the stack structure STK. In an embodiment, the contact region CTR might not have a stepped structure. The number of the conductive layers CD and the interlayer insulating layers IL stacked and included in the stack structure STK in the contact region CTR may be substantially the same regardless of their locations in an XY plane. Lengths of the conductive layers CD in the X direction (or lengths in the Y direction) included in the stack structure STK may be substantially equal. For example, lengths in the X direction of a first conductive layer CD1, a second conductive layer CD2, and a third conductive layer CD3, which are disposed at different heights (e.g., locations on a Z-axis) in the stack structure STK, may be substantially equal.

The contact plugs CT may extend in the Z direction in the contact region CTR. The contact plugs CT may respectively extend from different conductive layers CD. For example, the first contact plug CT1 may extend in the Z direction from the first conductive layer CD1. In addition, the second contact plug CT2 may extend in the Z direction from the second conductive layer CD2. The contact plugs CT may be integrally formed with the conductive layers CD, respectively. For example, the first contact plug CT1 may be integrally formed with the first conductive layer CD1. In addition, the second contact plug CT2 may be integrally formed with the second conductive layer CD2. The contact plugs CT may contact the conductive layers CD, respectively. The contact plugs CT may be electrically coupled to the conductive layers CD, respectively.

The length of the first contact plug CT1 in the Z direction and the length of the second contact plug CT2 in the Z direction may differ from each other. As the second conductive layer CD2 is located farther in the Z direction than the first conductive layer CD1, the length of the second contact plug CT2 in the Z direction may be smaller than that of the first contact plug CT1 in the Z direction. Though not shown in FIG. 3B, a contact plug coupled to the third conductive layer CD3 may have a smaller length in the Z direction than the second contact plug CT2.

The contact plugs CT may penetrate at least one of the conductive layers CD and at least one of the interlayer insulating layers IL. The contact plugs CT may penetrate the conductive layers CD that are located farther in the Z direction than a corresponding conductive layer CD coupled to each contact plug CT. For example, the first contact plug CT1 may penetrate the conductive layers CD (e.g., the second conductive layer CD2 and the third conductive layer CD3) that are located farther in the Z direction than the first conductive layer CD1. In addition, the second contact plug CT2 may penetrate the conductive layers CD (e.g., the third conductive layer CD3) that are located farther in the Z direction than the second conductive layer CD2. The contact plugs CT may penetrate the interlayer insulating layers IL that are located farther in the Z direction than a corresponding conductive layer CD electrically coupled to each contact plug CT. For example, the first contact plug CT1 may penetrate the interlayer insulating layers IL (e.g., a first interlayer insulating layer IL1, a second interlayer insulating layer IL2, and a third interlayer insulating layer IL3) that are located farther in the Z direction than the first conductive layer CD1. In addition, the second contact plug CT2 may penetrate the interlayer insulating layers IL (e.g., the second interlayer insulating layer IL2 and the third interlayer insulating layer IL3) that are located farther in the Z direction than the second conductive layer CD2. As the stack structure STK does not have a stepped structure in the contact region CTR, the contact plugs CT may penetrate the conductive layers CD and the interlayer insulating layers IL. The contact plugs CT may penetrate the upper insulating layer UIL.

The contact plugs CT may include tungsten (W), cobalt (Co), nickel (Ni), molybdenum (Mo), silicon (Si), polysilicon (poly-Si), or a combination of at least two of these materials. The contact plugs CT may have a single layer or multiple layers.

In FIG. 3B, the first contact plug CT1 and the second contact plug CT2 are shown for convenience of description, but the scope of the present disclosure is not limited thereto. For example, the memory device 100 may include only one contact plug CT or may include three or more contact plugs CT.

Spacers SP may surround side surfaces of the contact plugs CT, respectively. A first spacer SP1 may surround a side surface of the first contact plug CT1, and a second spacer SP2 may surround a side surface of the second contact plug CT2. For example, the spacers SP may be respectively formed on inner walls of openings extending in the Z direction in the stack structure STK. The contact plugs CT may be formed in regions surrounded by the spacers SP. The spacers SP may separate the contact plugs CT from corresponding conductive layers CD that each contact plug CT penetrates. For example, the first spacer SP1 may separate the first contact plug CT1 from the second conductive layer CD2 and the third conductive layer CD3. In addition, the second spacer SP2 may separate the second contact plug CT2 from the third conductive layer CD3. Accordingly, each of the contact plugs CT may be electrically coupled to a target conductive layer CD and may be insulated from other conductive layers CD except for the target conductive layer CD by the spacer SP.

Each of the spacers SP may include first material patterns 1ML and second material patterns 2ML. The first material patterns 1ML and the second material patterns 2ML may be alternately stacked in the Z direction. The first material patterns 1ML may be disposed between the contact plugs CT and the conductive layers CD. The second material patterns 2ML may be disposed between the contact plugs CT and the interlayer insulating layers IL. For example, the first material patterns 1ML of the first spacer SP1 may be disposed between the first contact plug CT1 and the conductive layers CD (e.g., the second conductive layer CD2 and the third conductive layer CD3). The second material patterns 2ML of the first spacer SP1 may be disposed between the first contact plug CT1 and the interlayer insulating layers IL (e.g., the second interlayer insulating layer IL2 and the third interlayer insulating layer IL3). The first material patterns 1ML of the second spacer SP2 may be disposed between the second contact plug CT2 and the conductive layers CD (e.g., the third conductive layer CD3). The second material patterns 2ML of the second spacer SP2 may be disposed between the second contact plug CT2 and the interlayer insulating layers IL (e.g., the third interlayer insulating layer IL3).

Each of the first material patterns 1ML and the second material patterns 2ML may have a ring shape that surrounds a side surface of the contact plug CT. Alternatively, each of the first material patterns 1ML and the second material patterns 2ML may have a cylindrical shape that surrounds the side surface of the contact plug CT.

An outer surface of each of the first material patterns 1ML may contact each of the conductive layers CD. An inner surface of each of the first material patterns 1ML may contact the contact plug CT. The inner surface of each of the first material patterns 1ML may include a convex surface that protrudes toward the contact plug CT.

The first material patterns 1ML may contact side surfaces of the conductive layers CD. A length of each of the first material patterns 1ML in the Z direction may be greater than or equal to a length of each of the conductive layers CD in the Z direction. Accordingly, the first material patterns 1ML may contact the side surfaces of the conductive layers CD and may also contact a portion of the side surfaces of the interlayer insulating layers IL. That is, the first material patterns 1ML may completely cover the side surfaces of the conductive layers CD at interfaces between the first material patterns 1ML and the stack structure STK. The first material patterns 1ML may block the side surfaces of the conductive layers CD from making electrical contact with the contact plugs CT. As the first material patterns 1ML cover the side surfaces of the conductive layers CD, the contact plug CT might not contact other conductive layers CD except for the target conductive layer CD. For example, the first contact plug CT1 may be insulated from other conductive layers CD (e.g., the second conductive layer CD2 and the third conductive layer CD3) except for the first conductive layer CD1 by the first material patterns 1ML of the first spacer SP1.

An outer surface of each of the second material patterns 2ML may contact each of the interlayer insulating layers IL. An inner surface of each of the second material patterns 2ML may contact the contact plug CT. The inner surface of each of the second material patterns 2ML may include a convex surface that protrudes toward the contact plug CT. The second material patterns 2ML may protrude farther toward the contact plug CT than the first material patterns 1ML. An upper surface and a lower surface of each of the second material patterns 2ML may contact neighboring first material patterns 1ML.

The second material patterns 2ML may be disposed between the first material patterns 1ML adjacent to each other in the Z direction. The second material patterns 2ML may cover a side surface of the stack structure STK that is not covered by the first material patterns 1ML. That is, the second material patterns 2ML may cover side surfaces of the interlayer insulating layers IL that are exposed between the first material patterns 1ML. Each of the second material patterns 2ML may fill a space between the first material patterns 1ML adjacent to each other in the Z direction. Accordingly, the contact plugs CT may be spaced apart from the conductive layers CD and the interlayer insulating layers IL.

The first material patterns 1ML may be disposed at an uppermost portion and a lowermost portion of each of the spacers SP. Accordingly, the spacers SP might not be located between the contact plugs CT and the upper insulating layer UIL. For example, the contact plugs CT may contact a side surface of the upper insulating layer UIL. In addition, the spacers SP might not be located between the contact plugs CT and any one of the interlayer insulating layers IL. Each of the contact plugs CT may contact the interlayer insulating layer IL that is disposed directly on top of a corresponding conductive layer CD coupled to each contact plug CT. For example, the first contact plug CT1 may contact the first interlayer insulating layer IL1 and the second contact plug CT2 may contact the second interlayer insulating layer IL2. Even when the contact plugs CT contact the upper insulating layer UIL and one of the interlayer insulating layers IL, because the upper insulating layer UIL and the interlayer insulating layer IL are electrically insulated from each other, a bridge phenomenon in which the contact plug CT is coupled to two or more conductive layers CD does not occur.

The side surface of each of the contact plugs CT may have concave portions that curve inwards. For example, concave portions each corresponding to respective first material patterns 1ML or second material patterns 2ML may be formed on the side surface of each of the contact plugs CT. The concave portions may contact the first material patterns 1ML or the second material patterns 2ML, respectively. The concave portions include a first concave portion contacting at least one of the first material patterns 1ML and a second concave portion contacting at least one of the second material patterns 2ML.

Each of the contact plugs CT may have different widths according to locations in the Z direction. For example, the first contact plug CT1 may include first portions contacting the first material patterns 1ML and second portions contacting the second material patterns 2ML. The first portions and the second portions may be alternately stacked in the Z direction. Each of the first portions encircled by a first material pattern 1ML may have a width greater than a width of each of the second portions encircled by a second material pattern 2ML in a horizontal direction (e.g., the X direction). For example, referring a minimum width of each of the first portions as a first width W1 and a minimum width of each of the second portions as a second width W2, the first width W1 may be greater than the second width W2. As the second material patterns 2ML protrude farther toward the contact plugs CT than the first material patterns 1ML, the second width W2 may be smaller than the first width W1.

The first material patterns 1ML may include a material that is selectively deposited on a nitride layer. For example, the first material patterns 1ML may include silicon oxycarbide (SiOC). The second material patterns 2ML may include an oxide layer. For example, the second material patterns 2ML may include a silicon oxide layer.

According to an embodiment of the present disclosure, because the contact plug CT and the conductive layer CD are formed integrally, the loss of voltages applied to the conductive layers CD may be reduced. In addition, because the dielectric constants of the first material patterns 1ML and the second material patterns 2ML may be lower compared to those in the prior art, the capacity between the conductive layers CD (e.g., the second conductive layer CD2 and the third conductive layer CD3) that the contact plug CT penetrates and the contact plug CT (e.g., the first contact plug CT1) may be reduced.

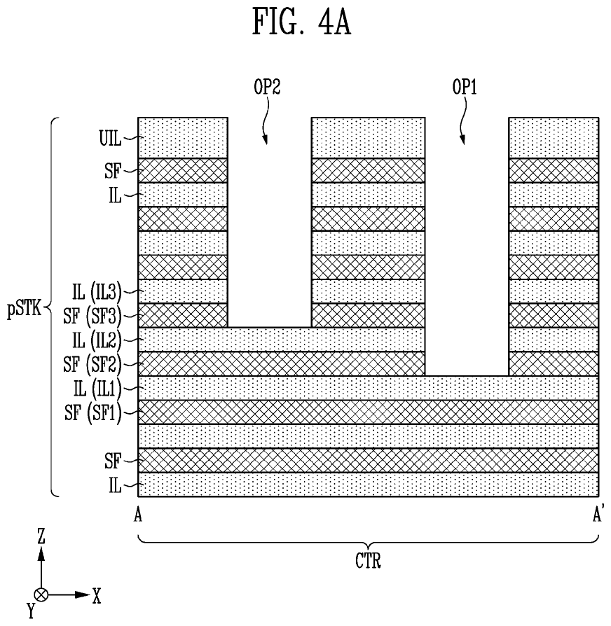

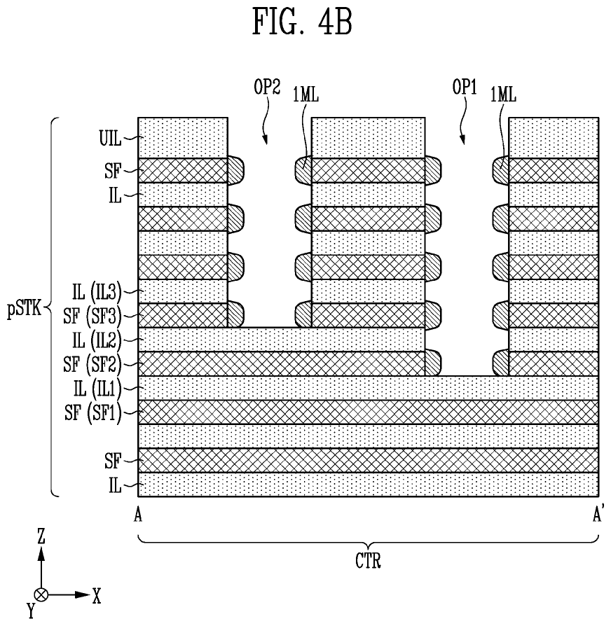

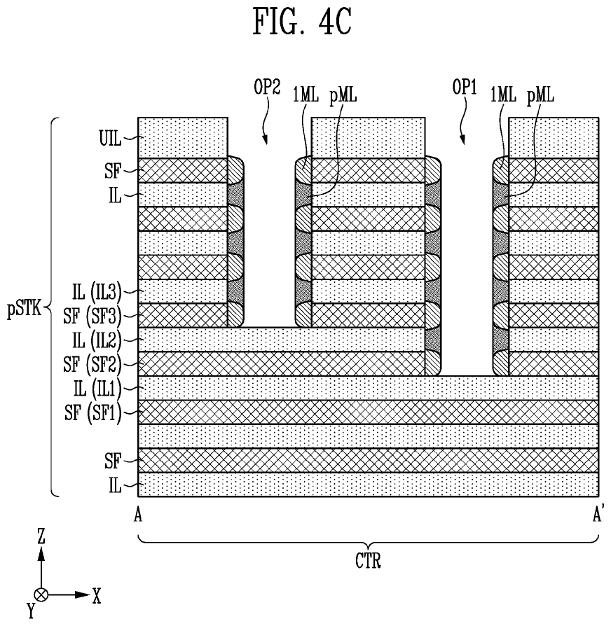

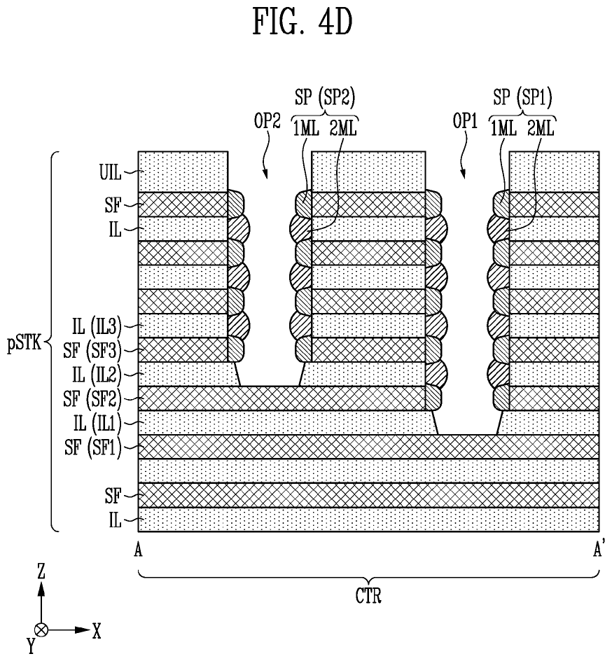

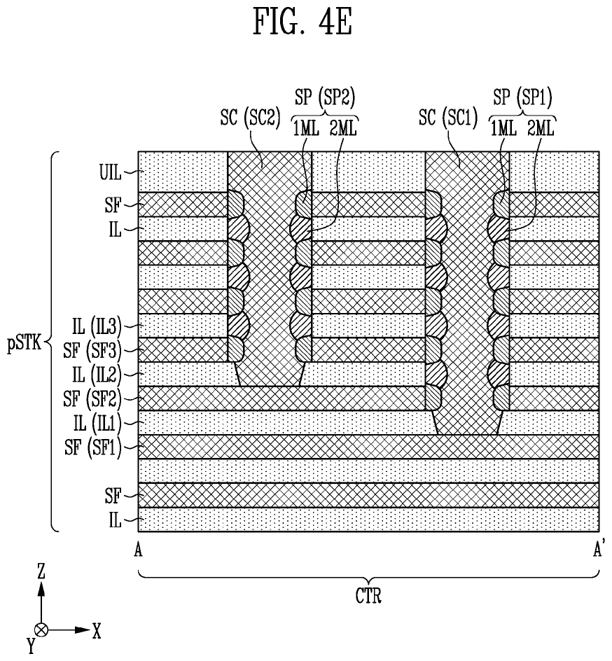

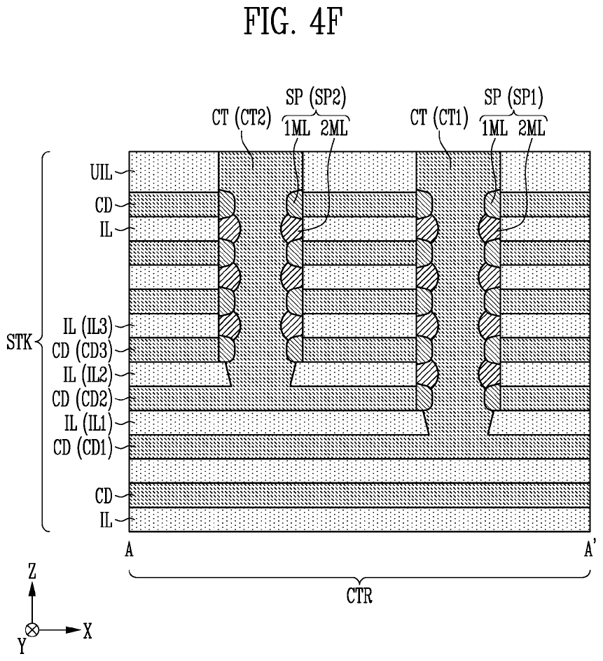

FIGS. 4A to 4F are diagrams illustrating a manufacturing method of forming a contact plug and a spacer according to an embodiment of the present disclosure. FIGS. 4A to 4F each show a cross-section taken along line A-A′ of FIG. 3A.

Referring to FIG. 4A, a preliminary stack structure pSTK in which the interlayer insulating layers IL and sacrificial layers SF are alternately stacked may be formed. The interlayer insulating layers IL and the sacrificial layers SF may be alternately stacked in the Z direction. The interlayer insulating layers IL may include an insulating material. For example, the interlayer insulating layers IL may include an oxide layer (e.g., a silicon oxide layer). The sacrificial layers SF may include a material that may be selectively removed in a subsequent process. The sacrificial layers SF may include a material having an etch selectivity different from that of the interlayer insulating layers IL. For example, the sacrificial layers SF may include a nitride layer.

The preliminary stack structure pSTK may further include the upper insulating layer UIL. The upper insulating layer UIL may be formed over an uppermost sacrificial layer SF among the sacrificial layers SF. The upper insulating layer UIL may include the same material as the interlayer insulating layers IL. The upper insulating layer UIL may have a greater thickness in the Z direction than each of the interlayer insulating layers IL.

Subsequently, openings OP1 and OP2 extending in the Z direction may be formed in the preliminary stack structure pSTK. The openings OP1 and OP2 may penetrate the upper insulating layer UIL, at least one sacrificial layer SF, and at least one interlayer insulating layer IL. For example, a first opening OP1 may penetrate a second sacrificial layer SF2, the second interlayer insulating layer IL2, a third sacrificial layer SF3, and the third interlayer insulating layer IL3. In addition, a second opening OP2 may penetrate the third sacrificial layer SF3 and the third interlayer insulating layer IL3. Each of the openings OP1 and OP2 may represent a hole extending in the Z direction. Side surfaces of the upper insulating layer UIL, at least one sacrificial layer SF, and at least one interlayer insulating layer IL may be exposed at side surfaces of the openings OP1 and OP2.

Lower surfaces of the openings OP1 and OP2 may expose the interlayer insulating layers IL1 and IL2, respectively. Each of the openings OP1 and OP2 may have a depth (e.g., a length in the Z direction) that exposes a different interlayer insulating layer IL. For example, the first interlayer insulating layer IL1 may be exposed through the lower surface of the first opening OP1, and the second interlayer insulating layer IL2 may be exposed through the lower surface of the second opening OP2.

Referring to FIG. 4B, the first material patterns 1ML may be selectively formed on the sacrificial layers SF exposed through the openings OP1 and OP2. The first material patterns 1ML may be selectively deposited on side surfaces of the sacrificial layers SF. For example, the first material patterns 1ML may be layers that are grown from surfaces of the sacrificial layers SF.

The first material patterns 1ML may include a material that may be selectively deposited on a nitride material (e.g., the sacrificial layers SF). For example, the first material patterns 1ML may include a material that may be selectively deposited on the material included in the sacrificial layers SF (e.g., a silicon nitride (SiN)). For example, the first material patterns 1ML may include silicon oxycarbide (SiOC).

The length of each of the first material patterns 1ML in the Z direction may be greater than a length of each of the sacrificial layers SF in the Z direction. For example, the first material patterns 1ML may cover the surfaces of the sacrificial layers SF and may also cover a portion of surfaces of the interlayer insulating layers IL. The side surfaces of the sacrificial layers SF are not be exposed due to the first material patterns 1ML. The interlayer insulating layers IL may be exposed between consecutive first material patterns 1ML in the Z direction.

As the first opening OP1 has a greater depth than the second opening OP2, the number of sacrificial layers SF exposed through the first opening OP1 may be greater than the number of sacrificial layers SF exposed through the second opening OP2. Accordingly, the number of first material patterns 1ML formed on the side surface of the first opening OP1 may be greater than the number of first material patterns 1ML formed on the side surface of the second opening OP2.

Referring to FIG. 4C, preliminary material patterns pML may be formed between the first material patterns 1ML. Between the first material patterns 1ML adjacent to each other in the Z direction, the preliminary material patterns pML may contact the interlayer insulating layers IL. For example, a preliminary material layer may be formed conformally on inner walls of the openings OP1 and OP2 in which the first material patterns 1ML are formed, and then a portion of the preliminary material layer may be removed to form the preliminary material patterns pML. The preliminary material patterns pML might not protrude farther into the openings OP1 and OP2 than the first material patterns 1ML. The preliminary material patterns pML may include polysilicon (poly-Si). The side surfaces of the interlayer insulating layers IL may be covered by the preliminary material patterns pML. The preliminary material patterns pML may be absent from the side surface of the upper insulating layer UIL. For example, the preliminary material layer formed on the side surface of the upper insulating layer UIL may be removed.

Referring to FIG. 4D, the interlayer insulating layer IL exposed through each of the openings OP1 and OP2 may be etched. For example, a portion of the first interlayer insulating layer IL1 that is exposed through the lower surface of the first opening OP1 may be removed. In addition, a portion of the second interlayer insulating layer IL2 that is exposed through the lower surface of the second opening OP2 may be removed. A wet etching process may be performed to etch a portion of the exposed interlayer insulating layer IL through the lower surface of each of the openings OP1 and OP2.

A width (or a diameter) of a region where each of the interlayer insulating layers IL is etched through the opening OP1 or OP2 may be smaller than a width (or a diameter) of each of the openings OP1 and OP2 penetrating the upper insulating layer UIL. For example, the width of the first opening OP1 may be smaller at a level corresponding to the first interlayer insulating layer IL1 than at a level corresponding to the upper insulating layer UIL. A region where the first interlayer insulating layer IL1 is etched through the first opening OP1 may have a smaller area (or a smaller volume) than a region where the second interlayer insulating layer IL2 is etched through the first opening OP1. A portion of the first interlayer insulating layer IL1 which is covered by the first material pattern 1ML might not be etched because a portion of the first interlayer insulating layer IL1 which is exposed through the lower surface of the first opening OP1 is etched. In addition, the first opening OP1 may have a tapered shape at the level corresponding to the first interlayer insulating layer IL1.

Because the interlayer insulating layers IL1 and IL2 are etched through the openings OP1 and OP2, respectively, the sacrificial layers SF1 and SF2, respectively, may be exposed through the openings OP1 and OP2. For example, a first sacrificial layer SF1 may be exposed through the lower surface of the first opening OP1. In addition, the second sacrificial layer SF2 may be exposed through the lower surface of the second opening OP2.

Subsequently, the preliminary material patterns pML may be changed to the second material patterns 2ML. The preliminary material patterns pML may be oxidized to form the second material patterns 2ML. A volume of the second material patterns 2ML may be greater than that of the preliminary material patterns pML, as the second material patterns 2ML are formed by oxidizing the preliminary material patterns pML. Accordingly, the second material patterns 2ML may protrude farther toward a center of each of the openings OP1 and OP2 than the first material patterns 1ML. The inner surface of each of the second material patterns 2ML may protrude farther into each of the openings OP1 and OP2 than the inner surface of each of the first material patterns 1ML. The second material patterns 2ML may include a silicon oxide layer.

The first and second material patterns 1ML and 2ML that are alternately stacked in the Z direction may form the spacer SP. The first and second material patterns 1ML and 2ML that are formed in the first opening OP1 may form the first spacer SP1. The first and second material patterns 1ML and 2ML that are formed in the second opening OP2 may form the second spacer SP2.

Referring to FIG. 4E, sacrificial pillars SC may be formed in the first and second openings OP1 and OP2. The sacrificial pillars SC may fill in the first and second openings OP1 and OP2. Each of the sacrificial pillars SC may contact a different sacrificial layer SF. For example, a first sacrificial pillar SC1 may contact the first sacrificial layer SF1. In addition, a second sacrificial pillar SC2 may contact the second sacrificial layer SF2. The sacrificial pillars SC may include a nitride. For example, the sacrificial pillars SC may include a material identical to or of a similar composition to that of the sacrificial layers SF.

Referring to FIG. 4F, the sacrificial layers SF and the sacrificial pillars SC may be replaced with a conductive material. For example, the sacrificial layers SF and the sacrificial pillars SC may be removed, and the conductive layers CD and the contact plugs CT may be formed in the spaces from which the sacrificial layers SF and the sacrificial pillars SC were removed by filling the spaces with a conductive material. The conductive layers CD may be formed in spaces where the sacrificial layers SF were removed, and the contact plugs CT may be formed in spaces where the sacrificial pillars SC were removed. The conductive layers CD and the interlayer insulating layers IL may form the stack structure STK. The contact plugs CT may be disposed in the stack structure STK.

The conductive layers CD and the contact plugs CT may be formed simultaneously. The conductive layers CD and the contact plugs CT might not have boundaries therebetween because the conductive layers CD and the contact plugs CT are formed simultaneously. For example, the first conductive layer CD1 and the first contact plug CT1 may be formed integrally without a boundary or seam between the first conductive layer CD1 and the first contact plug CT1. In addition, the second conductive layer CD2 and the second contact plug CT2 may be formed integrally without a boundary or seam between the second conductive layer CD2 and the second contact plug CT2.

According to an embodiment of the present disclosure, the contact plugs CT and the conductive layers CD may be formed simultaneously, which may simplify the process and reduce the process cost and time.

The conductive material may include tungsten (W), cobalt (Co), nickel (Ni), molybdenum (Mo), silicon (Si), polysilicon (poly-Si), an aluminum oxide (Al₂O₃), or a combination of at least two of these materials. For example, the conductive layers CD and the contact plugs CT may have a single layer including tungsten (W), cobalt (Co), nickel (Ni), molybdenum (Mo), silicon

(Si), or polysilicon (poly-Si), or may have multiple layers including at least two of tungsten (W), cobalt (Co), nickel (Ni), molybdenum (Mo), silicon (Si), polysilicon (poly-Si), and an aluminum oxide (Al₂O₃).

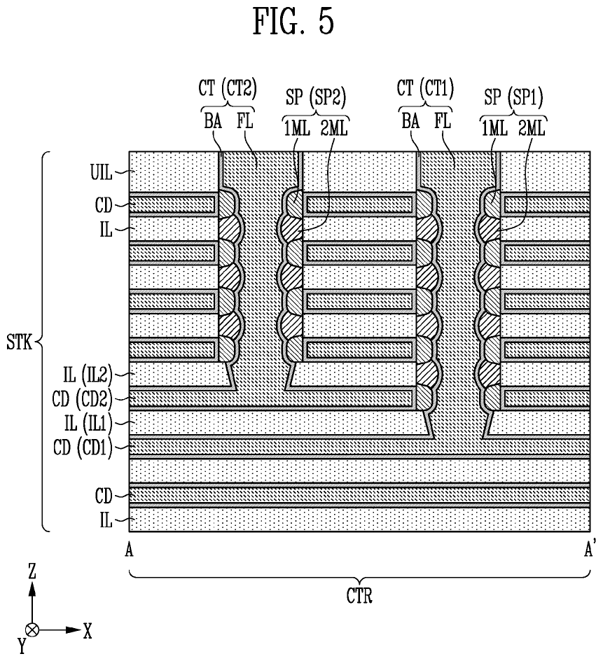

FIG. 5 is a diagram illustrating a structure of a contact plug according to another embodiment of the present disclosure. Descriptions of configurations that have already been described with reference to FIGS. 3A, 3B, and 4A to 4F are omitted or simplified.

FIG. 5 shows an embodiment of the contact plugs CT having multiple layers. Referring to FIG. 5, each of the contact plugs CT may include a barrier layer BA and a filling layer FL. The barrier layer BA may surround a surface of the filling layer FL. For example, when the sacrificial layers SF and the sacrificial pillars SC are replaced with the conductive material in FIG. 4F, the barrier layer BA may be formed on a surface defined by a space left from where each of the sacrificial layers SF and the sacrificial pillars SC was removed, and subsequently, the filling layer FL may fill in a space surrounded by the barrier layer BA.

The barrier layer BA may include aluminum oxide (Al₂O₃). The filling layer FL may include at least one of tungsten (W), cobalt (Co), nickel (Ni), molybdenum (Mo), silicon (Si), or polysilicon (poly-Si).

Referring to FIG. 5, the conductive layers CD and the contact plugs CT might not be separated by the barrier layer BA because the conductive layers CD and the contact plugs CT are formed simultaneously. For example, a filling layer FL included in the first contact plug CT1 and a filling layer FL included in the first conductive layer CD1 may be formed consecutively, but not be separated by the barrier layer BA. In addition, a filling layer FL included in the second contact plug CT2 and a filling layer FL included in the second conductive layer CD2 may be formed consecutively, but not be separated by the barrier layer BA.

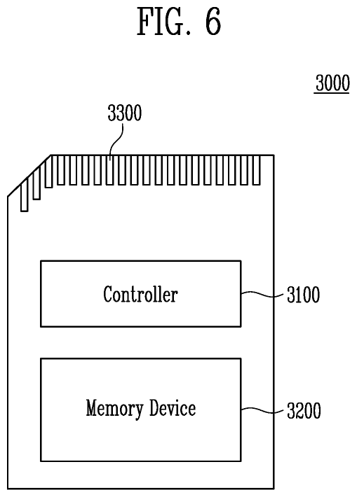

FIG. 6 is a diagram illustrating a memory card system 3000 to which a memory device according to an embodiment of the present disclosure is applied.

Referring to FIG. 6, the memory card system 3000 may include a controller 3100, a memory device 3200, and a connector 3300.

The controller 3100 may be coupled to the memory device 3200. The controller 3100 may be configured to access the memory device 3200. For example, the controller 3100 may be configured to control a program operation, a read operation, or an erase operation of the memory device 3200 or control a background operation. The controller 3100 may be configured to provide an interface between the memory device 3200 and a host. The controller 3100 may be configured to drive firmware for controlling the memory device 3200. For example, the controller 3100 may include components such as Random-Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as a Personal Computer Memory Card International Association (PCMCIA) card, a Compact Flash (CF) card, a Smart Media Card (SM and SMC), a memory stick, a Multi-Media Card (MMC, RS-MMC, MMCmicro, or eMMC), a Secure Digital (SD) card (SD, miniSD, microSD, or SDHC), and a Universal Flash Storage (UFS).

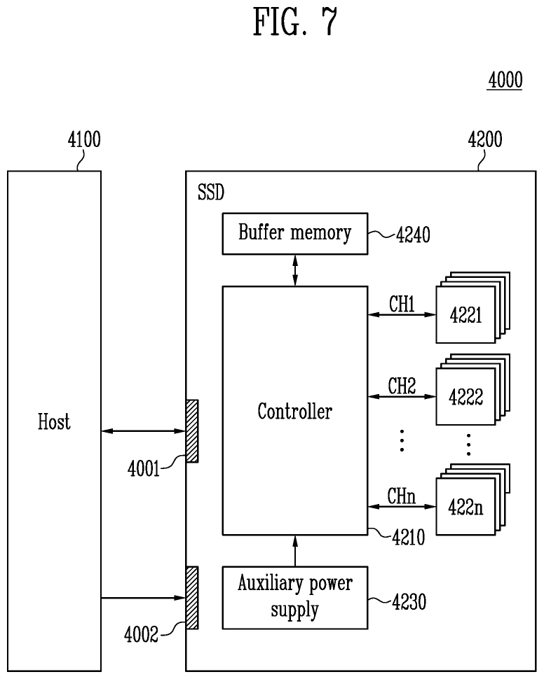

FIG. 7 is a diagram illustrating a solid-state drive (SSD) system 4000 to which a memory device according to an embodiment of the present disclosure is applied.

Referring to FIG. 7, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be defined by at least one of interfaces such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive and be charged with a power voltage from the host 4100. When the supply of power from the host 4100 is not smooth, the auxiliary power supply 4230 may provide a power voltage of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memory such as DRAM, SDRAM, DDR SDRAM, and LPDDR SDRAM, or non-volatile memory such as FRAM, ReRAM, STT-MRAM, and PRAM.

According to some embodiments of the present disclosure, the performance of contact plugs may be improved and the forming process of the contact plugs may be simplified by changing structures of the contact plugs and spacers.

What is claimed is:

1. A memory device, comprising:
conductive layers and interlayer insulting layers alternately stacked in a first direction;
a contact plug extending in the first direction from a first conductive layer among the conductive layers; and
a spacer surrounding at least a portion of a side surface of the contact plug,
wherein the spacer includes first material patterns and second material patterns alternately stacked in the first direction.

2. The memory device of claim 1, wherein the conductive layers include a second conductive layer disposed above the first conductive layer, and
wherein the contact plug penetrates the second conductive layer.

3. The memory device of claim 2, wherein the spacer separates the contact plug from the second conductive layer.

4. The memory device of claim 2, wherein the interlayer insulating layers include a first interlayer insulating layer disposed between the first conductive layer and the second conductive layer, and
wherein the contact plug is in contact with the first interlayer insulating layer.

5. The memory device of claim 1, wherein at least one of first material patterns is disposed between the contact plug and at least one of the conductive layers.

6. The memory device of claim 1, wherein each of the second material patterns is disposed between two adjacent first material patterns in the first direction.

7. The memory device of claim 1, wherein at least one of the second material patterns is disposed between the contact plug and at least one of the interlayer insulating layers.

8. The memory device of claim 1, wherein each of the first material patterns and each of the second material patterns is shaped as a ring and surrounds at least a portion of the side surface of the contact plug.

9. The memory device of claim 1, wherein at least one of the first material patterns includes an outer surface contacting one of the conductive layers.

10. The memory device of claim 1, wherein each of the second material patterns includes:
an outer surface contacting one of the interlayer insulating layers;
an upper surface contacting and adjacent first material pattern, of the first material patterns, above the second material pattern; and
a lower surface contacting an adjacent first material pattern, of the first material patterns, below the second material pattern.

11. The memory device of claim 1, wherein each of the first material patterns and each of the second material patterns includes an inner surface that has a convex shape toward the contact plug and that contacts the contact plug.

12. The memory device of claim 1, wherein the side surface of the contact plug includes concave portions that curve inward toward the contact plug.

13. The memory device of claim 12, wherein the concave portions include a first concave portion contacting at least one of the first material patterns and a second concave portion contacting at least one of the second material patterns.

14. The memory device of claim 1, wherein the second material patterns protrude farther toward the contact plug than the first material patterns.

15. The memory device of claim 1, wherein a width of each of the second material patterns is greater than a width of each of the first material patterns.

16. The memory device of claim 1, wherein the contact plug includes:
first portions contacting the first material patterns, respectively; and
second portions contacting the second material patterns, respectively, and
wherein each of the first portions has a greater width than each of the second portions.

17. The memory device of claim 1, wherein the contact plug and the first conductive layer are integrally formed.

18. A method of manufacturing a memory device, the method comprising:
alternately stacking sacrificial layers and interlayer insulating layers in a first direction;
forming an opening into the stacked layers exposing a first interlayer insulating layer among the interlayer insulating layers;
forming a spacer on side surfaces of the sacrificial layers and the interlayer insulating layers exposed through the opening, wherein the spacer includes first material patterns and second material patterns alternately stacked in the first direction;
removing a portion of the first interlayer insulating layer exposed through the opening to expose a first sacrificial layer among the sacrificial layers;
forming a sacrificial pillar contacting the first sacrificial layer in the opening; and
replacing the sacrificial layers and the sacrificial pillar with a conductive material.

19. The method of claim 18, wherein forming the spacer includes:
forming the first material patterns on the side surfaces of the sacrificial layers exposed through the opening;
forming preliminary material patterns contacting, between the first material patterns, the interlayer insulating layers exposed through the opening, respectively; and
forming the second material patterns by oxidizing the preliminary material patterns.

20. The method of claim 19, wherein the second material patterns extend farther toward the center of the opening than the first material patterns.

21. The method of claim 18, wherein replacing the sacrificial layers and the sacrificial pillar with the conductive material includes:
removing the sacrificial layers and the sacrificial pillar;
forming conductive layers respectively in spaces from where the sacrificial layers were removed; and
forming a contact plug in the space from where the sacrificial pillar was removed.

22. The method of claim 21, wherein forming the conductive layers and forming the contact plug are performed together as part of the same operation resulting in a seamless connection between the contact plug and the conductive layer, of the conductive layers, to which the contact plug is electrically connected.
